(19) United States
(12) Patent Application Publication
(10) Pub. No.: US 2014/0028364 A1
(43) Pub. Date: Jan. 30, 2014

(54) CRITICAL PATH MONITOR HARDWARE ARCHITECTURE FOR CLOSED LOOP ADAPTIVE VOLTAGE SCALING AND METHOD OF OPERATION THEREOF

(71) Applicants: Ramnath Venkatraman, San Jose, CA (US); Prasad Subbarao, San Jose, CA (US); Ruggero Castagnetti, Menlo Park, CA (US)

(72) Inventors: Ramnath Venkatraman, San Jose, CA (US); Prasad Subbarao, San Jose, CA (US); Ruggero Castagnetti, Menlo Park, CA (US)

(73) Assignee: LSI Corporation, Milpitas, CA (US)

(21) Appl. No.: 13/560,371

(22) Filed: Jul. 27, 2012

(51) Int. Cl. H03K 5/14

(52) U.S. Cl. 327/262

(57) ABSTRACT

A critical path monitor (CPM), a method of setting supply voltage based on output of a CPM and an integrated circuit (IC) incorporating the CPM. In one embodiment, the CPM includes: (1) an edge detector configured to produce a thermometer output over a plurality of clock cycles and (2) a min_max recorder, coupled to the edge detector and configured to record minimum and maximum values of the thermometer output during a polling interval.

### TECHNICAL FIELD

This application is directed, in general, to a integrated circuits (ICs) and, more specifically, to ICs employing adaptive voltage scaling (AVS).

### BACKGROUND

Conserving resources, including energy, has become a pre-eminent objective in today's world. Manufacturers of ICs are sensitive to the need to improve the energy efficiency of their products. National Semiconductor Corporation developed adaptive voltage scaling (AVS) as part of that overall strategy. The idea behind adaptive voltage scaling is that an IC, such as an IC, could be powered based on its actual electrical characteristics and current operating temperature, both of which in part determine signal propagation speed.

AVS employs a closed control loop in which an AVS controller dynamically adjusts the supply voltage (V) provided by a voltage regulator to the IC based on the output of one or more critical path monitors (CPMs) reflecting the process condition of the IC substrate (P) and the temperature (T) at which the IC is operating. V is chosen based on P and T such that, barring an extreme condition, the IC's specified performance is guaranteed.

In carrying out AVS, it is important to know at any given instant in time of the amount of “slack” that is available in critical paths in the IC at a given clock frequency. A positive slack indicates that the supply voltage may be reduced without compromising performance, whereas a negative slack indicates that the functionality of one or more critical paths is already compromised and that the supply voltage should be increased to regain proper functionality. A slack of zero is optimal and therefore the goal of the AVS controller.

### SUMMARY

One aspect of the invention provides a CPM. In one embodiment, the CPM includes: (1) an edge detector configured to produce a thermometer output over a plurality of clock cycles and (2) a min_max recorder, coupled to the edge detector and configured to record minimum and maximum values of the thermometer output during a polling interval.

Another aspect provides a method of setting supply voltage based on output of a CPM. In one embodiment, the method includes: (1) monitoring the output of an edge detector of the CPM over a plurality of clock cycles, (2) recording a minimum value of a thermometer output of the edge detector over a polling interval, (3) recording a maximum value of a thermometer output of the edge detector over the polling interval, (4) calculating a weighted average of the minimum and maximum values and (5) setting a supply voltage to an integrated circuit based on the weighted average.

Yet another aspect provides an IC. In one embodiment, the IC includes: (1) an adaptive voltage scaling controller and (2) at least one CPM coupled to the adaptive voltage scaling controller, the at least one CPM. In one embodiment, the CPM has: (1) an edge detector configured to produce a thermometer output over a plurality of clock cycles and (2) a min_max recorder, coupled to the edge detector and configured to record minimum and maximum values of the thermometer output during a polling interval.

### BRIEF DESCRIPTION

Reference is now made to the following descriptions taken in conjunction with the accompanying drawings, in which:

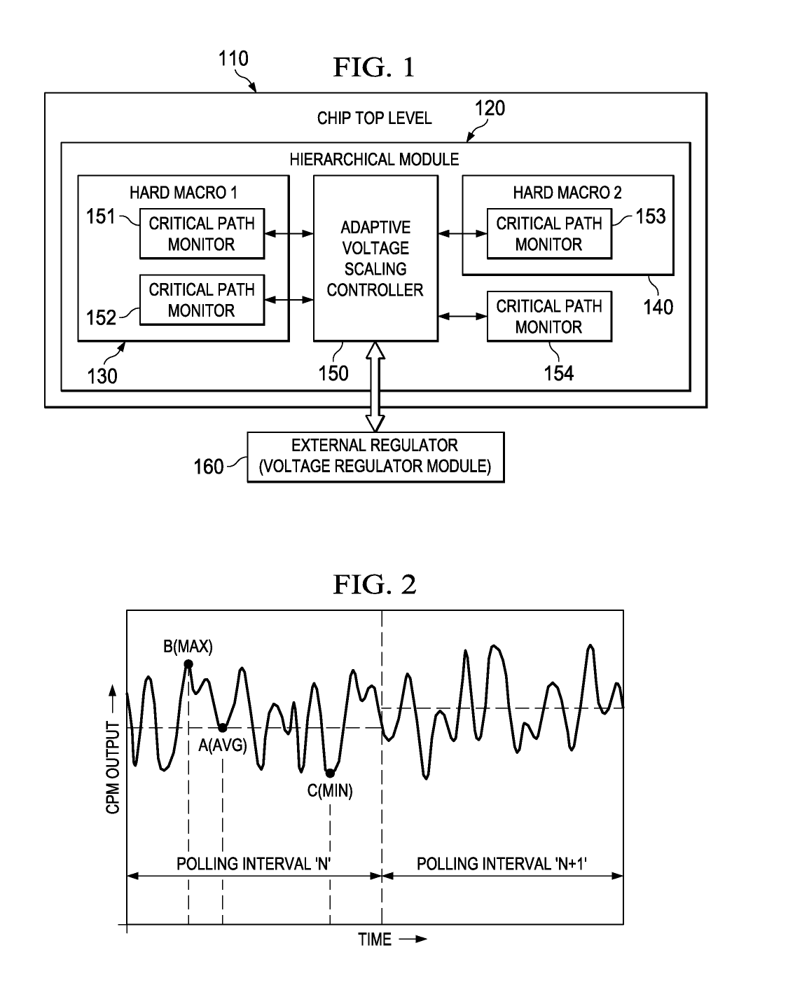

FIG. 1 is a block diagram of one embodiment of an IC employing AVS;

FIG. 2 is a graph illustrating an example of the output of a CPM over sequential polling intervals;

FIG. 3 is a block diagram of one embodiment of a CPM;

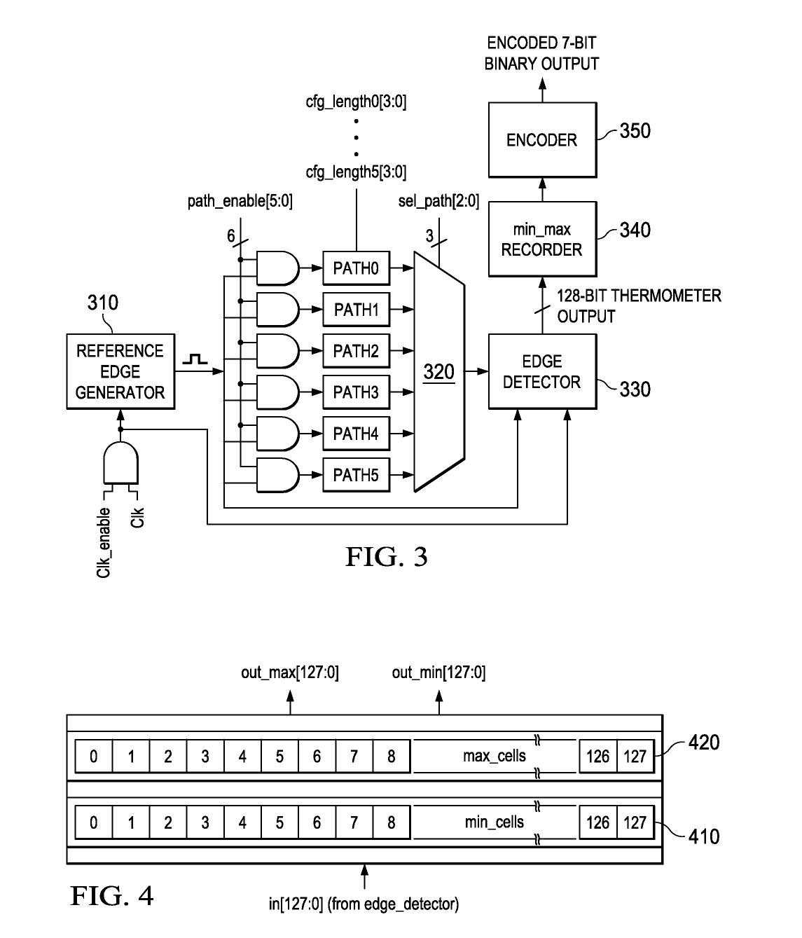

FIG. 4 is a diagram of min and max recorder subblocks of the min_max recorder of FIG. 3;

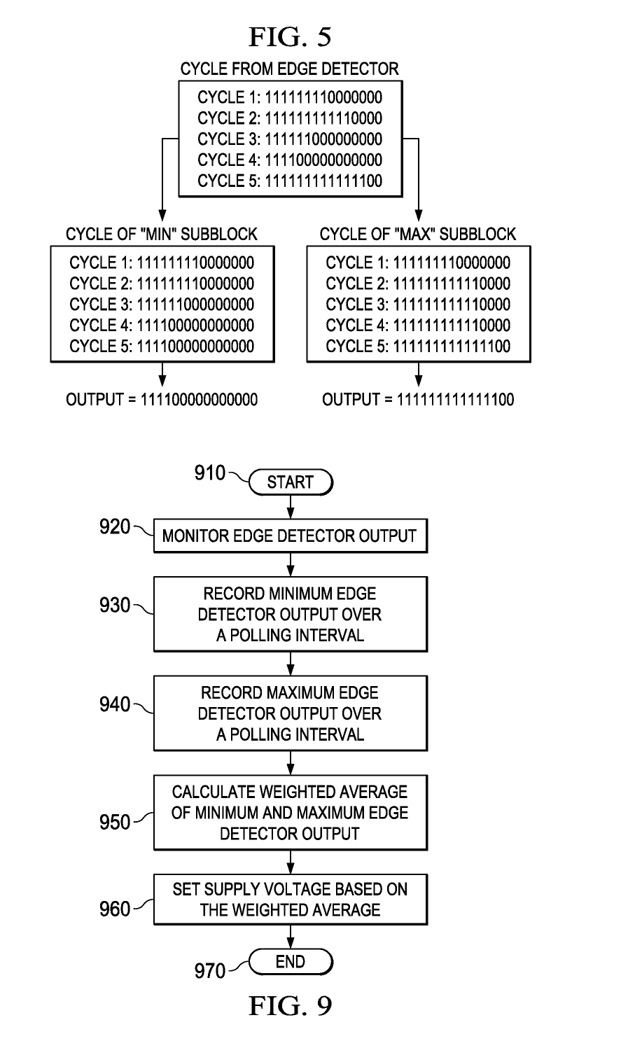

FIG. 5 is a representation of example edge detector output states over sequential clock cycles and resulting min_max recorder states over the clock cycles;

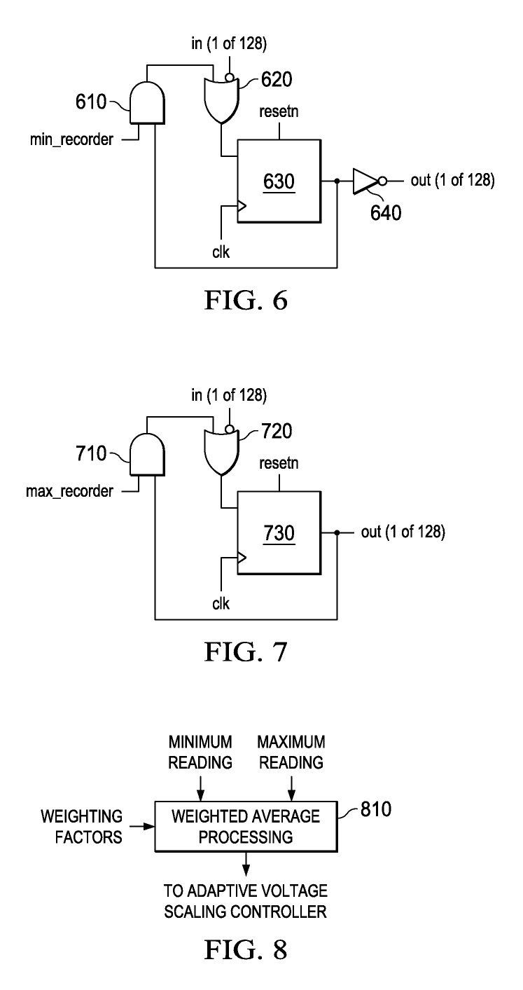

FIG. 6 is a schematic diagram of one embodiment of a min recorder cell of the min recorder subblock of FIG. 4;

FIG. 7 is a schematic diagram of one embodiment of a max recorder cell of the max recorder subblock of FIG. 4;

FIG. 8 is a block diagram of one embodiment of a weighted average processing block of the min_max recorder of FIG. 3;

FIG. 9 is a method of setting supply voltage based on the output of a CPM; and

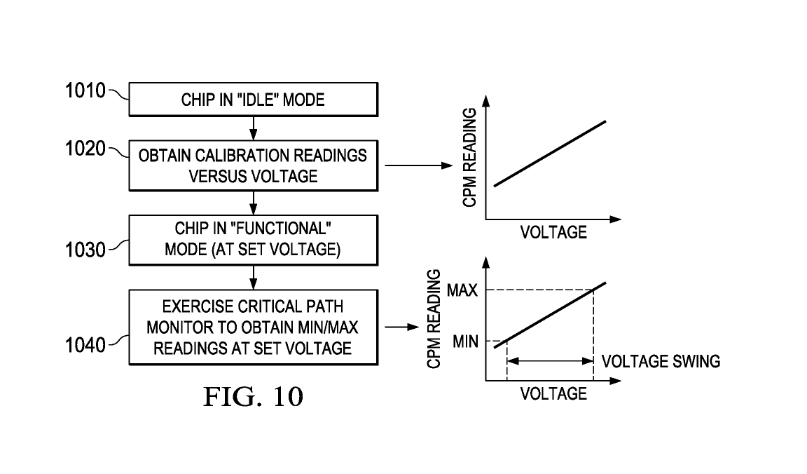

FIG. 10 is a flow diagram of one embodiment of a method of employing the min_max recorder of FIG. 3 as a worst-case voltage drop monitor.

### DETAILED DESCRIPTION

As described above, the AVS controller dynamically adjusts the supply voltage provided by a voltage regulator to the IC based on the output of one or more CPMs. The voltage supplied by the voltage regulator is constant at a given regulator setting (called a voltage ID, or VID). Nonetheless, as those skilled in the pertinent art are aware, the actual voltage at various points within the chip are likely to vary considerably due to voltage drops associated with static and dynamic currents in the IC (the latter depending on switching activity). Therefore the CPM should be capable of measuring slack dynamically, thus taking into account the voltage fluctuations on the IC.

Most modern CPMs fall into two general categories: ring-oscillator-based CPMs and delay-path-based CPMs. Ring-oscillator-based CPMs have a time-base larger than the IC's system clock frequency (which drives the ring-oscillator) and therefore do not have an adequate cycle-by-cycle sensitivity. For this reason, ring-oscillator-based CPMs are inappropriate for the embodiments disclosed herein and will not be further described.

In contrast, delay-path-based CPMs do have a suitable cycle-by-cycle sensitivity, allowing such CPMs to track sharp fluctuations due to instantaneous voltage drops (IVDs) on the IC. Delay-path-based CPMs use the IC's system clock as a reference for launching data into one or more pre-designed, independent data paths. The delay in the data path(s) is monitored with the expectation that, by design, one or more of the paths will closely track the delay behavior along an actual critical path in the IC. This allows the AVS controller to correlate the output of the CPM directly to the slack available in the actual critical path.

The AVS controller polls the various CPMs to which it is coupled in time intervals that are at least as long as the frequency at which the voltage regulator is capable of changing the supply voltage it provides to the IC. The specifications of voltage controllers that are commercially available today constrain the polling time interval to be at least 1 microsecond. This time interval is much larger compared to the typical system clock cycle times of modern ICs, which are on the order of ˜0.5 ns to 10 ns. For this reason, the AVS controller should choose a VID that most fairly represents the slack information the CPMs provide over the polling time interval.

Introduced herein are various embodiments of a CPM architecture and a method of performing AVS that provide better data to the AVS controller to allow it to make better VID decisions. Before describing the various embodiments in detail, an example of an IC employing AVS will now be given. FIG. 1 is a block diagram of one embodiment of an IC (or, more colloquially, “chip”) employing AVS. The IC is hierarchical in its organization and has circuitry arranged in a top level 110 and a hierarchical module 120 containing a hard macro 1 130 and a hard macro 2 140. An AVS controller 150 receives data from various CPMs 151, 152, 153, 154. The CPMs 151, 152 are associated with the hard macro 1 130; the CPM 153 is associated with the hard macro 2 140; and the CPM 154 is generally associated with the hierarchical module 120. The AVS controller 150 provides a VID (not shown) to a voltage regulator 160, which happens to be a module (VRM) external to the IC.

FIG. 2 is a graph illustrating an example of the output of a CPM over sequential polling intervals, specifically polling interval ‘n’ and polling interval ‘n+1.’ FIG. 2 shows that CPM output can vary significantly within a given polling interval. If, as shown in FIG. 2, the CPM is polled at time A, the CPM's output will be close to the average CPM output over the polling cycle. However, if the CPM is polled at time B, the CPM's output reading will be close to the maximum CPM output value over the polling interval. If, on the other hand, the CPM is polled at time C, the CPM's output reading will be close to the minimum CPM output value over the polling interval. Since the time at which the CPM is polled bears no relation to the activity on the IC and hence the CPM's output, the output reading could be a poor representation of the CPM's output over the whole of the interval. Consequently, the VID the AVS controller chooses could be dramatically incorrect, perhaps leading to wasted power or unreliable, perhaps unsafe, IC operation.

To address this issue, the CPM architecture and method of performing AVS provide more representative data regarding the CPM's output during a given time interval. The AVS controller therefore has more or better information from which to make its VID decisions. In various embodiments to be illustrated and described, the novel architecture and method include a CPM that provides multiple types of data to the AVS controller. In certain embodiments, the CPM provides either or both of minimum and maximum output values achieved during the interval. In alternative embodiments, the CPM itself combines the data to yield resulting data that is more representative of its output over the interval. In one embodiment to be illustrated and described, weighting factors are employed to generate a weighted average of minimum and maximum output values.

In various embodiments to be illustrated and described, the CPM is provided with a circuit, which may be composed of sequential logic, that enables the CPM simultaneously to record (a) the minimum reading over a given polling interval, (b) the maximum reading over a given polling interval and (c) a calculated weighted reading that considers both the minimum and maximum readings.

Turning now to FIG. 3, illustrated is a block diagram of one embodiment of a CPM, which may be one or more of the CPMs 151, 152, 153, 154 of FIG. 1. The CPM includes a system-clock-driven reference edge generator 310 that provides data (rising or falling edges of a square waveform) to one or more delay paths. The embodiment of FIG. 3 is shown as having six delay paths: path0, path1, path2, path3, path4, path5. A path selection multiplexer 320 is configured to select the delay path that best represents a corresponding critical path (not shown, but part of the circuitry with which the CPM is associated (e.g., hard macro 1 130, hard macro 2 140 or the hierarchical module 120 of FIG. 1).

An edge detector 330 is configured to detect how far the pulse edge introduced into the delay path has advanced through the selected delay path (e.g., path0, path1, path2, path3, path4, path5) during one clock cycle. The thermometer output of the edge detector 330 takes the form of a series of ones followed by a series of zeros. The boundary betweens ones and zeros demarcates how far the edge has advanced through the selected delay path and through the edge detector 330. For this reason, the output of the edge detector 330 is colloquially called a “thermometer output.” In one embodiment, the edge detector 330 has a 128-bit thermometer output.

A min_max recorder 340 is configured to receive the thermometer output of the edge detector 330 and, in a manner to be described below, employ the thermometer output to generate additional data that can then be employed to improve AVS accuracy.

An encoder 350 is configured then to receive and encode the output of the min_max recorder 340 to yield an encoded CPM output reading suitable for transmission to the AVS controller (e.g., the AVS controller 150 of FIG. 1). In one embodiment, the encoded CPM output reading is seven bits long. In one embodiment, the min_max recorder 340 provides multiple types of data (e.g., both a minimum reading and a maximum reading) to the encoder 350 for encoding. In an alternative embodiment, the min_max recorder 340 provides only one type of data (e.g., a weighted average of minimum and maximum readings) to the encoder 350 for encoding. In one embodiment, the encoder 350 encodes multiple types of data (e.g., minimum and maximum readings) separately (e.g., using separate encoders). In an alternative embodiment, the encoder 350 encodes the multiple types of data in succession (e.g., in successive clock cycles).

The general operation of the embodiment of the min_max recorder 340 of FIG. 3 will now be described. Turning to FIG. 4, illustrated is a representation of example edge detector output states over sequential clock cycles and resulting min_max recorder states over the clock cycles.

Various embodiments of the min_max recorder 340 will now be described. FIG. 4 is a diagram of min_max recorder subblocks of cells in the min_max recorder embodiment of FIG. 3. FIG. 4 shows a min recorder subblock 410 having 128 min recorder cells and a max recorder subblock 420 likewise having 128 max recorder cells. The 128 min recorder cells of the min recorder subblock 410 and the 128 max recorder cells of the max recorder subblock 420 are coupled to corresponding lines of a 128-bit output bus (“in [127:0]”) bearing the thermometer output of the edge detector 330. The 128 min recorder cells 410 and the 128 max recorder cells are respectively further coupled to respective, separate max and min output buses (“out_min [127:0]” and “out_max [127:0]”). The logic of min and max recorder subblocks within the min_max recorder 340 are such that they respectively record the minimum and maximum thermometer output values encountered during the plurality of clock cycles.

Turning to FIG. 5, the operation of the embodiments of the min and max recorder subblocks 410, 420 of FIG. 4 will now be described by example. FIG. 5 shows the states of an example 15-bit thermometer output over five consecutive clock cycles as they are provided to the min and max recorder subblocks 410, 420 of FIG. 4. As is apparent, boundaries between ones and zeros in the output states occur after bit 8 in cycle 1, after bit 11 in cycle 2, after bit 6 in cycle 3, after bit 4 in cycle 4 and after bit 13 in cycle 5. For purposes of this example, the output state will be said to have a value of eight in cycle 1, a value of 11 in cycle 2, a value of six in cycle 3, a value of four in cycle 4 and a value of 13 in cycle 5. It is also apparent that, based on these output states, the min recorder value should be four, and the max recorder output value should be 13 after cycle 5.

The min recorder subblock initially assumes the value of the thermometer output of the edge detector during the first cycle, retains its value during the second cycle, assumes the value of the thermometer output of the edge detector during the third and fourth cycles and retains its value during the fifth cycle. This results in a min recorder value of four, as expected. The max recorder subblock initially assumes the value of the thermometer output of the edge detector during the first cycle, assumes the value of the thermometer output of the edge detector during the second cycle, retains its value during the third and fourth cycles and assumes the value of the thermometer output of the edge detector during the fifth cycle. This results in a max recorder value of 13, as expected.

FIG. 6 is a schematic diagram of one embodiment of a min recorder cell (just one of 128) of the min recorder subblock of FIG. 4. FIG. 6 is presented for the purpose of illustrating how the cells of the min recorder subblock may be configured to achieve a min recorder value.

The min recorder cell includes an AND gate 610, an OR gate 620, a flip-flop 630 and an inverter 640 coupled as shown. When the flip-flop 630 is reset, the min recorder cell assumes the value of ‘1’ and remains ‘1’ as long as its input is a ‘1.’ As soon as the input becomes a ‘0,’ its output remains ‘0’ and does not change until the flip-flop 630 is once again reset. This results in the minimum reading being recorded over an interval of time as the example of FIG. 5 illustrated. In one embodiment, an additional ‘min-recorder’ pin is included, which enables this behavior when maintained at ‘1’. When the ‘min-recorder’ pin is maintained at ‘0,’ the min-recorder cell assumes the value at the input. The logic of the min recorder cell of FIG. 6 is arranged such that upon a reset, the output of the min recorder cell is a ‘1’ rather than a ‘0’, thus allowing the ‘min-recorder’ pin to be transitioned to ‘1’ from the beginning of the cell's operation (rather than have the additional operating requirement of transitioning the ‘min-recorder’ pin to ‘1’ after clocking the data paths for a few clock cycles).

FIG. 7 is a schematic diagram of one embodiment of a max recorder cell (just one of 128) of the max recorder subblock of FIG. 4. FIG. 7 is presented for the purpose of illustrating how the cells of the max recorder subblock may be configured to achieve a max recorder value.

The max recorder cell includes an AND gate 710, an OR gate 720 and a flip-flop 730 coupled as shown. When the flip-flop 730 is reset, the max recorder cell assumes the value of ‘0’ and remains ‘0’ as long as its input is a ‘0.’ As soon as the input becomes a ‘1,’ its output remains ‘1’ and does not change until the flip-flop 730 is once again reset. This results in the maximum reading being recorded over an interval of time as the example of FIG. 5 illustrated. In one embodiment, an additional ‘max-recorder’ pin is included, which enables this behavior when maintained at ‘1’. When the ‘max-recorder’ pin is maintained at ‘0,’ the max-recorder cell assumes the value at the input. The logic of the max recorder cell of FIG. 7 is arranged such that upon a reset, the output of the min recorder cell is a ‘0’ rather than a ‘1’, thus allowing the ‘max-recorder’ pin to be transitioned to ‘0’ from the beginning of the cell's operation (rather than have the additional operating requirement of turning transitioning the ‘max-recorder’ pin to ‘0’ after clocking the data paths for a few clock cycles).

FIG. 8 is a block diagram of one embodiment of a weighted average processing block of the min_max recorder of FIG. 3. As stated above, the CPM may itself combine the minimum and maximum output values encountered during the clock cycles to yield resulting data that is more representative of its output over the interval and then provide that combined data to the AVS controller, perhaps in encoded form. FIG. 8 is directed to that embodiment, and more specifically to an embodiment in which weighting factors are employed to generate a weighted average of the minimum and maximum output values. Accordingly, FIG. 8 illustrates a weighted average processing block 810 that takes as its input the minimum and maximum output values (readings) and weighting factors (weights) and produces as its output a weighted average of the minimum and maximum output values. As those skilled in the art are aware, the weighting factors are typically chosen such that their sum equals one.

In one embodiment, the weighting factors are predetermined. In a specific embodiment, a programmable fuse (not shown) is employed to set the weighting factors. In an alternative embodiment, the weighting factors are dynamically adjusted to achieve a desired degree of pessimism or optimism, perhaps by way of a feedback loop.

The most pessimistic case is to use a weighting factor of one for the min output value and a weighting factor of zero for the max output value at all times. The most pessimistic case is to use a weighting factor of zero for the min output value and a weighting factor of one for the max output value at all times. A moderate case is to use a weighting factor of 0.5 for both the min and max output values. Those skilled in the art will understand that other cases may be appropriate for particular ICs in various applications and conditions.

It is possible that operational conditions may lead to a min output value of zero, which is typically an invalid number for purposes of determining voltage value. Accordingly, one embodiment of the CPM employs a setting, ‘cfglength,’ illustrated in FIG. 3 that can be employed to configure the length of the delay paths (e.g., path0, path1, path2, path3, path4, path5) to ensure that the output data remain in the range of the thermometer output of the edge detector 330.

FIG. 9 is a method of setting supply voltage based on the output of a CPM. The method begins in a start step 910. In a step 920, the output of an edge detector of a CPM is monitored over a plurality of clock cycles. In a step 930, the minimum value of the thermometer output of the edge detector is recorded over a polling interval. In a step 940, the maximum value of the thermometer output of the edge detector is recorded over a polling interval. In a step 950, a weighted average of the minimum and maximum values is calculated, perhaps just before the CPM is polled. In one embodiment, the minimum and maximum values are separately transmitted to an AVS controller when the CPM is polled, and the step 950 is carried out in the AVS controller. In an alternative embodiment, the step 950 is carried out in one or more CPMs, and the weighted average is transmitted to the AVS controller when the CPM is polled. In a step 960, the supply voltage to an IC is set based on the weighted average. The method ends in an end step 970.

FIG. 10 is a flow diagram of one embodiment of a method of employing the min_max recorder of FIG. 3 as a worst-case, instantaneous voltage drop monitor. To estimate the extent of voltage swings in a given interval of time, a given CPM can be first calibrated to optimize its output range versus its expected input voltage, as steps 1010, 1020 indicate. At the time of calibration, the minimum and maximum values produced by the edge detector are expected to be the same. This is followed by actual measurements when the IC is actually operating and experiencing voltage swings, as step 1030 indicates. The minimum and maximum edge detector output values are then employed to compute maximum voltage drops, as step 1040 indicates. If a CPM in a given IC is employed exclusively as a voltage drop monitor, the path delay architecture may be significantly simplified by providing only a single path instead of multiple paths as FIG. 3 shows.

Those skilled in the art to which this application relates will appreciate that other and further additions, deletions, substitutions and modifications may be made to the described embodiments.

1. A critical path monitor, comprising:
a single edge detector configured to produce a thermometer output over a plurality of clock cycles; and
a min_max recorder, coupled to said edge detector and configured to record minimum and maximum values of said thermometer output during a polling interval.

2. The monitor as recited in claim 1 wherein said min_max recorder is further configured to transmit said minimum and maximum values of said thermometer output to an adaptive voltage scaling controller.

3. The monitor as recited in claim 1 wherein said min_max recorder is further configured to compute a weighted average of said minimum and maximum values of said thermometer output and transmit said weighted average to an adaptive voltage scaling controller.

4. The monitor as recited in claim 1 wherein said critical path monitor has multiple delay paths and further comprises a path selection multiplexer configured to select one of said multiple delay paths.

5. The monitor as recited in claim 1 wherein said critical path monitor has a delay path of configurable length.

6. The monitor as recited in claim 1 further comprising an encoder coupled to said min_max recorder and configured to encode said minimum and maximum values.

7. The monitor as recited in claim 1 further comprising an encoder coupled to said min_max recorder and configured to encode a weighted average of said minimum and maximum values.

8. A method of setting supply voltage based on output of a critical path monitor, comprising:
monitoring an output of a single edge detector of said critical path monitor over a plurality of clock cycles;
recording a minimum value of a thermometer output of said edge detector over a polling interval;
recording a maximum value of a thermometer output of said edge detector over said polling interval;
calculating a weighted average of said minimum and maximum values; and
setting a supply voltage to an integrated circuit based on said weighted average.

9. The method as recited in claim 8 further comprising transmitting said minimum and maximum values of said output to an adaptive voltage scaling controller.

10. The method as recited in claim 8 further comprising:
computing a weighted average of said minimum and maximum values of said output; and
transmitting said weighted average to an adaptive voltage scaling controller.

11. The method as recited in claim 8 wherein said critical path monitor has multiple delay paths and said method further comprises selecting one of said multiple delay paths.

12. The method as recited in claim 8 further comprising configuring a length of a delay path of said critical path monitor.

13. The method as recited in claim 8 further comprising encoding said minimum and maximum values.

14. The method as recited in claim 8 further comprising encoding a weighted average of said minimum and maximum values.

15. An integrated circuit, comprising:
an adaptive voltage scaling controller; and
at least one critical path monitor coupled to said adaptive voltage scaling controller, said at least one critical path monitor including:
a single edge detector configured to produce a thermometer output over a plurality of clock cycles, and
a min_max recorder, coupled to said edge detector and configured to record minimum and maximum values of said thermometer output during a polling interval.

16. The integrated circuit as recited in claim 15 wherein said min_max recorder is further configured to transmit said minimum and maximum values of said thermometer output to said adaptive voltage scaling controller.

17. The integrated circuit as recited in claim 15 wherein said min_max recorder is further configured to compute a weighted average of said minimum and maximum values of said thermometer output and transmit said weighted average to said adaptive voltage scaling controller.

18. The integrated circuit as recited in claim 15 wherein said critical path monitor has multiple delay paths and further comprises a path selection multiplexer configured to select one of said multiple delay paths.

19. The integrated circuit as recited in claim 15 wherein said critical path monitor has a delay path of configurable length.

20. The integrated circuit as recited in claim 15 wherein said at least one critical path monitor further includes an encoder coupled to said min_max recorder and configured to encode said minimum and maximum values.

21. The integrated circuit as recited in claim 15 wherein said at least one critical path monitor further includes an encoder coupled to said min_max recorder and configured to encode a weighted average of said minimum and maximum values.
